(19) United States
(12) Patent Application Publication
(10) Pub. No.: US 2024/0237363 A1
(43) Pub. Date: Jul. 11, 2024

(54) TECHNIQUES FOR MODULAR DIE CONFIGURATIONS FOR MULTI-CHANNEL MEMORY

(71) Applicant: Micron Technology, Inc., Boise, ID (US)

(72) Inventors: James Brian Johnson, Boise, ID (US); Brent Keeth, Boise, ID (US); Ameen D. Akel, Rancho Cordova, CA (US); Kunal R. Parekh, Boise, ID (US); Amy Rae Griffin, Boise, ID (US); Eiichi Nakano, Boise, ID (US)

(21) Appl. No.: 18/400,994

(22) Filed: Dec. 29, 2023

Related U.S. Application Data
(60) Provisional application No. 63/438,333, filed on Jan. 11, 2023.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1434

(57) ABSTRACT

Methods, systems, and devices for modular die configurations for multi-channel memory are described. A semiconductor component (e.g., a semiconductor wafer) may be configured with multiple rows and multiple columns of memory arrays, and associated channels. A row of memory arrays may be associated with a contact region extending along the row direction. The semiconductor component may also include control regions extending along the column direction between at least some of the columns of memory arrays. Each control region may include control circuitry for operating memory arrays on one or both sides of the control region. The channels and memory arrays of the semiconductor wafer may be grouped into one or more independently-operable memory dies, with each memory die having at least a portion of a control region and at least a portion of a contact region for operating the memory arrays of the memory die.

### CROSS REFERENCE

The present application for patent claims the benefit of U.S. Provisional Patent Application No. 63/438,333 by Johnson et al., entitled “TECHNIQUES FOR MODULAR DIE CONFIGURATIONS FOR MULTI-CHANNEL MEMORY,” filed Jan. 11, 2023, which is assigned to the assignee hereof, and which is expressly incorporated by reference herein.

### TECHNICAL FIELD

The following relates to one or more systems for memory, including techniques for modular die configurations for multi-channel memory.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a system that supports techniques for modular die configurations for multi-channel memory in accordance with examples as disclosed herein.

FIG. 2 illustrates an example of a system that supports techniques for modular die configurations for multi-channel memory in accordance with examples as disclosed herein.

FIG. 3 illustrates an example of an architecture that supports techniques for modular die configurations for multi-channel memory in accordance with examples as disclosed herein.

FIG. 4 illustrates an example of a wafer layout that supports techniques for modular die configurations for multi-channel memory in accordance with examples as disclosed herein.

FIG. 5 illustrates an example of a die that supports techniques for modular die configurations for multi-channel memory in accordance with examples as disclosed herein.

FIG. 6 illustrates a flowchart showing a method or methods that support techniques for modular die configurations for multi-channel memory in accordance with examples as disclosed herein.

### DETAILED DESCRIPTION

In some memory systems, a memory die may include one or more memory regions (e.g., memory arrays) and one or more memory interfaces (e.g., channels) for accessing the one or more or more memory regions. Some such memory dies may be manufactured on a planar substrate, such as a semiconductor wafer, from which individual memory dies may be formed (e.g., diced) by separating the wafer along separation lines (e.g., scribe lines) of the substrate. In some examples, a semiconductor wafer layout may be specific to forming memory dies having a particular configuration (e.g., memory arrays and channels that are specific to a memory die design). However, such layouts may be associated with die configuration limitations, or yield limitations, among other issues.

As described herein, a wafer (e.g., a semiconductor wafer, a wafer including a substrate of crystalline semiconductor, a semiconductor component) may be configured to support multiple possible layouts of dies (e.g., semiconductor dies, memory dies, semiconductor subcomponents). For example, a wafer may include a pattern of memory arrays, arranged across the wafer in a pattern of rows and columns, as well as channels associated with accessing the memory arrays. A row of memory arrays may be associated with a contact region extending along the row direction, which may include contacts (e.g., conductive contacts, signal paths, contacts at a surface of the wafer) configured for communicating signaling associated with accessing memory arrays of the row (e.g., signaling associated with the channels). The wafer may also include control regions extending along the column direction between at least some columns of memory arrays, and each control region may include control circuitry for operating memory arrays on one or both sides (e.g., along the row direction) of the control region. The memory arrays and channels of the semiconductor wafer may be grouped into independently-operable units (e.g., modules), each unit having at least a portion of a control region and at least a portion of a contact region for operating the memory arrays of the unit. The memory arrays and channels of the semiconductor wafer may further be grouped into one or more dies, separable from the wafer, each die including one or more units and, in some cases, one or more portions of a unit. Such an architecture may allow for various configurations of memory dies to be formed using a same wafer design. For example, memory dies of a first configuration may be formed by separating a wafer along set of separation regions of the wafer, and memory dies of a second configuration different from the first configuration may be formed by separating a wafer along a different set of the separation regions of the wafer.

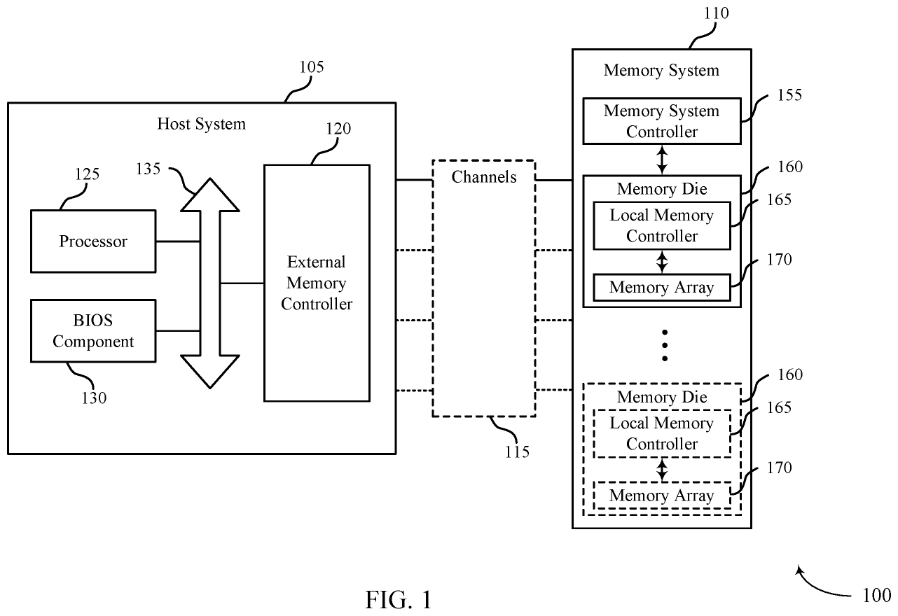

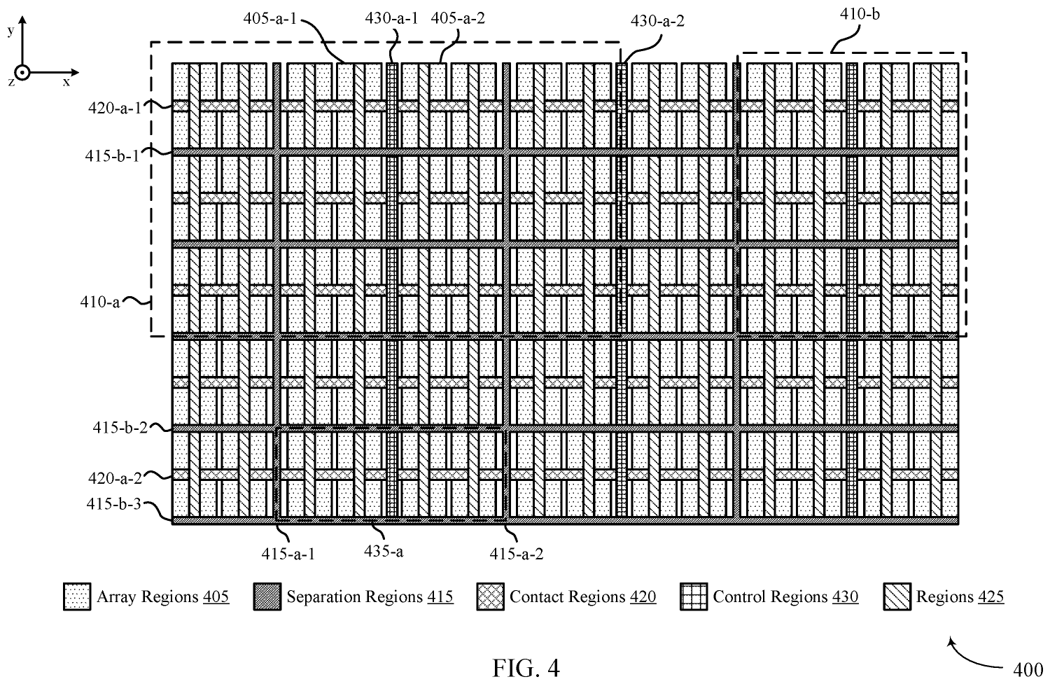

Features of the disclosure are initially illustrated and described in the context of systems. dies, and architectures as described with reference to FIGS. 1 through 3. Features of the disclosure are illustrated and described in the context of semiconductor components (e.g., wafers, dies) and a flowchart with reference to FIGS. 4 through 6.

FIG. 1 illustrates an example of a system 100 that supports techniques for modular die configurations for multi-channel memory in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processor (e.g., circuitry, processing circuitry, a processing component) that uses memory to execute processes, such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of an external memory controller 120, a processor 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., a memory system controller 155, a local memory controller 165) or vice versa. In various examples, the host system 105 or an external memory controller 120 may be referred to as a host.

A processor 125 may be operable to provide functionality (e.g., control functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof. In some examples, a processor 125 may be an example of a central processing unit (CPU), a graphics processing unit (GPU), a general-purpose GPU (GPGPU), or an SoC, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100. The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include a local memory controller 165 and a memory array 170. A memory array 170 may be a collection of memory cells, with each memory cell being operable to store one or more bits of data. A memory die 160 may include a two-dimensional (2D) array of memory cells, or a three-dimensional (3D) array of memory cells. In some examples, a 2D memory die 160 may include a single memory array 170. In some examples, a 3D memory die 160 may include two or more memory arrays 170, which may be stacked or positioned beside one another (e.g., relative to a substrate).

A local memory controller 165 may include components (e.g., circuitry, logic) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of a conductive input or output point of a device of the system 100, and a terminal may be operable to act as part of a channel 115.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal).

As described herein, memory dies 160 may be formed from a wafer that supports multiple configurations of memory dies 160. For example, a wafer may include a pattern of memory arrays, arranged across the wafer (e.g., in a pattern of rows and columns), as well as channels associated with accessing the memory arrays. A row of memory arrays may be associated with a contact region extending along the row direction, which may include contacts configured for communicating signaling associated with accessing memory arrays of the row (e.g., signaling associated with the channels). The wafer may also include control regions extending along the column direction between at least some columns of memory arrays, and each control region may include control circuitry for operating memory arrays on one or both sides (e.g., along the row direction) of the control region. The memory arrays and channels of the semiconductor wafer may be grouped into independently-operable units (e.g., modules) that may be separated from the semiconductor wafer, with each unit including at least a portion of a control region and at least a portion of a contact region for operating the associated memory arrays. For example, a memory die 160 may be formed by separating (e.g., dicing) a set of one or more units from the wafer, such that the separated units make up the memory die 160. Such an architecture may allow for various configurations of memory dies to be formed using a same wafer design, such as with different quantities or configurations of units.

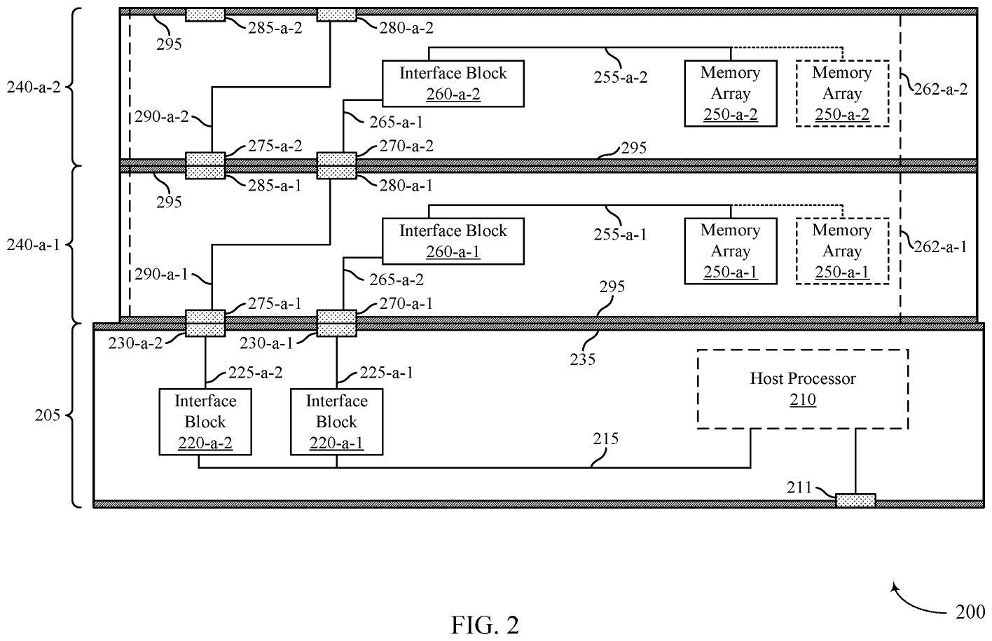

FIG. 2 illustrates an example of a system 200 (e.g., a semiconductor system, a system of coupled semiconductor dies) that supports techniques for modular die configurations for multi-channel memory in accordance with examples as disclosed herein. The system 200 illustrates an example of a die 205 (e.g., a semiconductor die, a host die, a processor die, a logic die) that is coupled with one or more dies 240 (e.g., dies 240-a-1 and 240-a-2, semiconductor dies, memory dies, array dies). A die 205 or a die 240 may be formed using a respective semiconductor substrate (e.g., a substrate of crystalline semiconductor material such as silicon, germanium, silicon-germanium alloy, gallium arsenide or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 coupled with a die 205.

The system 200 illustrates an example of interface circuitry between a host and memory that is implemented in (e.g., divided between) multiple semiconductor dies. For example, the die 205 may include a set of one or more interface blocks 220 (e.g., interface blocks 220-a-1 and 220-a-2, memory interface blocks), and each die 240 may include a set of one or more interface blocks 260 and one or more memory arrays 250 (e.g., die 240-a-1 including an interface block 260-a-1 coupled with a set of one or more memory arrays 250-a-1, die 240-a-2 including an interface block 260-a-2 coupled with a set of one or more memory arrays 250-a-2). In some implementations, the die 205 also may include a host processor 210. However, in some other implementations, a host processor 210 may be external to a die 205, such as in another semiconductor die or other component that is coupled with (e.g., communicatively coupled with, directly coupled with) the die 205 via one or more contacts 211. Although the example of system 200 is illustrated with one interface block 260 included in each die 240, a die 240 in accordance with the described techniques may include any quantity of one or more interface blocks 260, each coupled with a respective set of one or more memory arrays 250, and each coupled with a respective interface block 220 of a die 205. Thus, the interface circuitry of a system 200 may include one or more interface blocks 220 of a die 205, with each interface block 220 being coupled with (e.g., in communication with) a corresponding interface block 260 of a die 240 (e.g., external to the die 205).

The host processor 210 may be an example of a host system 105, or a portion thereof (e.g., a processor 125, an external memory controller 120, or both). The host processor 210 may be configured to perform operations that implement storage of the memory arrays 250. For example, the host processor 210 may receive data read from the memory arrays 250, or transmit data to be written to the memory arrays 250, or both (e.g., in accordance with an application or other operations of the host processor 210). The memory arrays 250 may be examples of memory arrays 170, and may include memory cells of various architectures, such as RAM, DRAM, SDRAM, SRAM, FeRAM, MRAM, RRAM, PCM, chalcogenide, NOR, or NAND memory cells, or any combination thereof. The host processor 210 may be configured to communicate (e.g., transmit, receive) signaling with the interface blocks 220 over a bus 215, which may implement aspects of channels 115 described with reference to FIG. 1. For example, the host processor 210 may be configured to transmit access signaling (e.g., control signaling, access command signaling), which may be received by the interface blocks 220 to support access operations (e.g., read operation, write operations) on the memory arrays 250.

A bus 215 may include a respective set of one or more signal paths for each interface block 220, such that the host processor 210 communicates with each interface block 220 over the respective set of signal paths (e.g., in accordance with a selection of the respective set to perform access operations via an interface block 220 that is selected by the host processor 210). Additionally, or alternatively, a bus 215 may include one or more signal paths that are shared among multiple interface blocks 220, and an interface block 220, or a host processor 210, or both may interpret, ignore, respond to, or inhibit response to signaling over shared signal paths of the bus 215 based on a logical indication (e.g., an addressing indication associated with the interface block 220 or an interface enable signal, which may be provided by the host processor 210 or the corresponding interface block 220, depending on signaling direction).

Each interface block 220 may be coupled with at least a respective bus 225 of the die 205, and a respective bus 265 of a die 240, that is configured to communicate signaling with the corresponding interface block 260 (e.g., over one or more associated signal paths). For example, the interface block 220-a-1 may be coupled with the interface block 260-a-1 via a bus 225-a-1 and a bus 265-a-1, and the interface block 220-a-2 may be coupled with the interface block 260-a-2 via a bus 225-a-2 and a bus 265-a-2. In some examples, a die 240 may include a bus that bypasses operational circuitry of the die 240 (e.g., bypasses interface blocks 260 of a given die 240), such as a bus 290. For example, the interface block 220-a-2 may be coupled with the interface block 260-a-2 of the die 240-a-2 via a bus 290-a-1 of the die 240-a-1, which may bypass interface blocks 260 of the die 240-a-1. Such techniques may be extended for interconnection among more than two dies 240 (e.g., for interconnection via a respective bus 290 of multiple dies 240).

The respective signal paths of the buses 225, 265, and 290 may be coupled with one another, from one die to another, via various arrangements of contacts at the surfaces of interfacing dies. For example, the bus 225-a-1 may be coupled with the bus 265-a-1 via a contact 230-a-1 of (e.g., at a surface of) the die 205 and a contact 270-a-1 of the die 240-a-1, the bus 225-a-2 may be coupled with the bus 290-a-1 via a contact 230-a-2 of the die 205 and a contact 275-a-1 of the die 240-a-1, the bus 290-a-1 may be coupled with the bus 265-a-2 via a contact 280-a-1 of the die 240-a-1 and a contact 270-a-2 of the die 240-a-2, and so on. Although each respective bus is illustrated with a single line, coupled via singular contacts, it is to be understood that each signal path of a bus may be associated with respective contacts to support a separate communicative coupling via each signal path of a given bus. In some examples, a bus 290 may traverse a portion of a die 240 (e.g., in an in-plane direction, along a direction different than a thickness direction, in a waterfall arrangement), which may support an arrangement of contacts 230 along a surface of the die 205 being coupled with interface blocks 260 of different dies 240 along a stack direction (e.g., via contacts 275 and 280 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205 with the die 240-a-1 may include a conductive material of the contact 230-a-2 being fused with a conductive material of the contact 275-a-1, and the coupling of the die 240-a-1 with the die 240-a-2 may include a conductive material of the contact 280-a-1 being fused with a conductive material of the contact 270-a-2, and so on. In some examples, such coupling may include an inoperative fusion of contacts (e.g., a non-communicative coupling, a physical coupling), such as a fusion of the contact 285-a-1 with the contact 275-a-2, neither of which are coupled with operative circuitry of the dies 240-a-1 or 240-a-2. In some examples, such techniques may be implemented to improve coupling strength or uniformity (e.g., implementing contacts 285, which may not be operatively coupled with an interface block 260 or an interface block 220), or such a coupling may be a byproduct of a repetition of components that, in various configurations, may be operative or inoperative. (e.g., where, for dies 240 with a common arrangement of contacts 275 and 285, contacts 275-a-1 and 280-a-1 provide a communicative path for the interface block 260-a-2 and the interface block 220-a-2, but the contacts 275-a-2 and 280-a-2 do not provide a communicative path between an interface block 260 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 235 (e.g., an electrically non-conductive material) of the die 205 being fused with a dielectric material 295 of the die 240-a-1, and the coupling of the die 240-a-1 with the die 240-a-2 may include a dielectric material 295 of the die 240-a-1 being fused with a dielectric material 295 of the die 240-a-2. In some examples, such dielectric materials may include an oxide, a nitride, a carbide, an oxide-nitride, an oxide-carbide, or other conversion or doping of a semiconductor material of the die 205 or dies 240, among other materials that may support such fusion. However, coupling among dies 205 and dies 240 may be implemented in accordance with other techniques, which may implement solder, adhesives, thermal interface materials, and other intervening materials.

In some examples, dies 240 may be coupled in a stack (e.g., forming a “cube” or other arrangement of dies 240), and the stack may subsequently be coupled with a die 205. In some examples, a respective set of one or more dies 240 may be coupled with each die 205 of multiple dies 205 formed in a wafer (e.g., in a chip-to-wafer bonding arrangement, before cutting the wafer of dies 205), and the dies 205, coupled with their respective set of dies 240, may be separated from one another (e.g., by cutting at least the wafer of dies 205). In some other examples, a respective set of one or more dies 240 may be coupled with a respective die 205 after the die 205 is separated from a wafer of dies 205 (e.g., in a chip-to-chip bonding arrangement).

The buses 225, 265, and 290 may be configured to provide a configured signaling (e.g., a coordinated signaling, a logical signaling, modulated signaling, digital signaling) between an interface block 220 and a corresponding interface block 260, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 260 (e.g., to trigger signal reception by a latch or other reception component of the interface block 260, to support clocked operations of the interface block 260). Additionally, or alternatively, the buses may be configured to convey one or more clock signals transmitted by the interface block 260 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication) of various, such as control signaling, command signaling, data signaling, or any combination thereof. For example, the buses may include one or more signal paths for communications of a data bus (e.g., a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220 and 260 each may include circuitry in various configurations (e.g., hardware configurations, logic configurations, software or instruction configurations) that support the functionality allocated to the respective interface block for accessing a corresponding set of memory arrays 250. For example, interface blocks 220 may include circuitry configured to perform a first subset of operations that support access of the memory arrays 250, and interface blocks 260 may include circuitry configured to support a second subset of operations that support access of the memory arrays 250. In some examples, the interface blocks 220 and 260 may support a functional split or distribution of functionality associated with a memory system controller 155, a local memory controller 165, or both across multiple dies (e.g., a die 205 and at least one die 240). Such subsets of operations may include operations performed in response to commands from the host processor 210, or operations performed without commands from the host processor 210 (e.g., operations determined within an interface block 220 or within an interface block 260), or various combinations thereof. The circuitry of interface blocks 220 and 260 may include components (e.g., transistors) formed at least in part from doped portions of a substrate of the respective die where, in some examples, a substrate of a die 205 may have characteristics that are different than those of a substrate of a die 240.

In some examples, the interface blocks 220 may include circuitry configured to receive first access command signaling from the host processor 210 (e.g., via a bus 215, via one or more contacts 211, where applicable), and to transmit second access command signaling to the respective (e.g., coupled) interface block 260 based on (e.g., in response to) the received first access command signaling. The interface blocks 260 may accordingly include circuitry configured to receive the second access command signaling from the respective interface block 220, and to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from the host processor 210, via a bus 215, via one or more contacts 211, where applicable) first data signaling associated with the first access command signaling, and to transmit second data signaling (e.g., associated with second access command signaling) based on received first access command signaling and first data signaling. The interface blocks 260 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 260 may be configured to read data from the memory arrays 250 based on received second access command signaling, and to transmit first data signaling based at least in part on the read data. The interface blocks 220 may accordingly be configured to receive first data signaling, and to transmit second data signaling (e.g., to the host processor 210, via a bus 215, via one or more contacts 211, where applicable) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted by the interface blocks 220 to the interface blocks 260 may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 (e.g., based on a configuration for accessing memory arrays 250 that is modified at the interface blocks 220). Such techniques may support the interface blocks 220 configuring aspects of the access operations performed on the memory arrays 250 by a respective interface block 260.

In some examples, dies 240 may be manufactured on a planar semiconductor component, such as a wafer, which may support multiple configurations of dies 240. For example, a wafer may include a pattern of memory arrays 250 arranged across the wafer along a row direction and a column direction, as well as channels, which may include at least buses 265, associated with the memory arrays 250. A row of memory arrays 250 may be associated with a contact region extending along the row direction, which may include contacts (e.g., contacts 270) for communicating access signaling with memory arrays 250 of the row. The wafer may also include control regions extending along the column direction between at least some of the columns of memory arrays 250, each control region containing control circuitry for operating memory arrays 250 (e.g., circuitry of an associated interface block 260). The wafer may also include a set of separation regions (e.g., scribe lines) separating at least some of the rows and columns of memory arrays 250.

A die 240 may include one or more units 262 (e.g., modules) that are separated from a semiconductor wafer having a pattern of units 262. Although each die 240 of the system 200 is illustrated with a single unit 262 (e.g., unit 262-a-1 of die 240-a-1, unit 262-a-2 of die 240-a-2), a die 240 in accordance with the described techniques may include any quantity of units 262, which may be arranged in various patterns (e.g., sets of one or more units 262 along a row direction, sets of one or more units 262 along a column direction, among other patterns). Each unit 262 may include at least the circuitry of a respective interface block 260, along with memory array(s) 250, a bus 255, a bus 265, and one or more contacts 270 corresponding to the respective interface block 260. In some examples, where applicable, each unit 262 may also include one or more buses 290, contacts 275, contacts 280, or contacts 285 (e.g., associated with a respective interface block 260 of a unit 262 of a different die 240), which may support various degrees of stackability among or via units 262 of other dies 240. As described herein, to support modular die configurations from a given wafer design, each unit 262 may include at least a portion of a control region of a wafer and at least a portion of a contact region of the wafer.

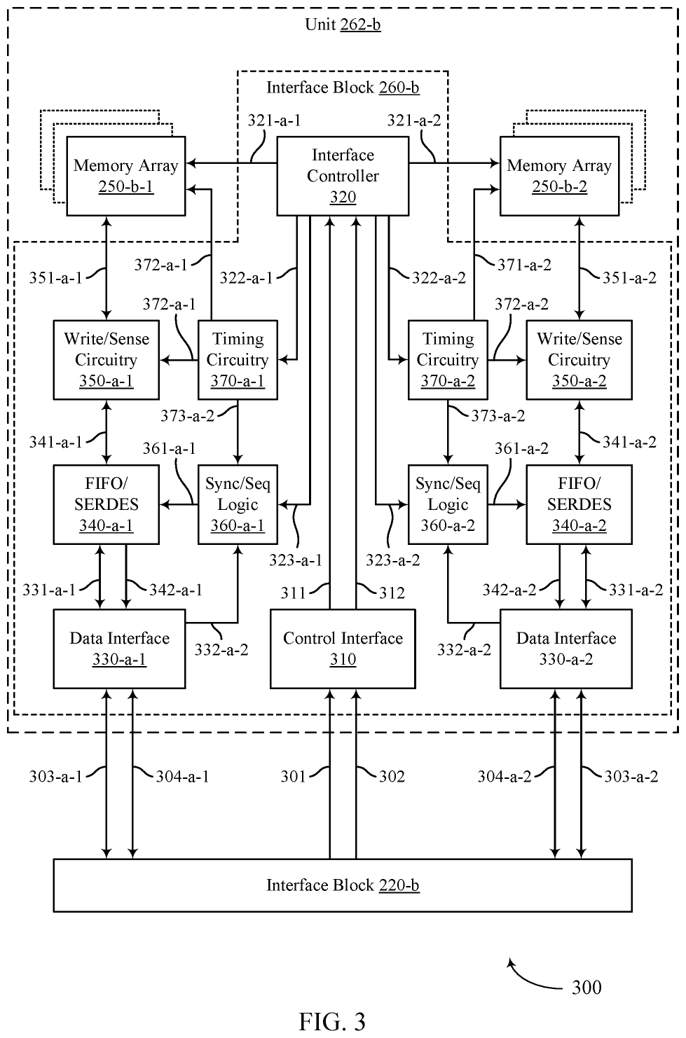

FIG. 3 illustrates an example of an architecture 300 that supports techniques for modular die configurations for multi-channel memory in accordance with examples as disclosed herein. The architecture 300 illustrates an example of an interface block 260-b (e.g., of a die 240) coupled with an interface block 220-b (e.g., of a die 205). The interface block 260-b may be communicatively coupled with the interface block 220-b via one or more channels, such as channels associated with a bus 301, a bus 302, a bus 303, and a bus 304, each of which may be examples of one or more signal paths of a bus 225 and a bus 265, as well as a bus 290, where applicable. Circuitry of the interface block 260-b may be included in an example of a unit 262-b along with its corresponding memory arrays 250-b.

The interface block 260-b includes a control interface 310 (e.g., a command interface), which may be configured to communicate signaling with the interface block 220-b. For example, the control interface 310 may include circuitry (e.g., a receiver, one or more latches) configured to receive control signaling (e.g., modulated control signaling, access command signaling, configuration signaling, address signaling, such as row address signaling or column address signaling) over the bus 301 (e.g., associated with a control channel). The control interface 310 also may include circuitry configured to receive clock signaling (e.g., clock signaling associated with the control interface 310, clock signaling having one or more phases, such as true and complement phases, dk_t/c signaling from the interface block 220-b) over the bus 302 (e.g., associated with a clock channel, such as a control clock channel), which the control interface 310 may use for receiving the control signaling of the bus 301 (e.g., for triggering the one or more latches). The control interface 310 may transmit (e.g., forward) the control signaling over a bus 311, and may transmit the clock signaling over a bus 312 (e.g., for timing of other operations of the interface block 260-b), each of which may be received by an interface controller 320.

The interface block 260-b also includes two data interfaces 330 (e.g., data interfaces 330-a-1 and 330-a-2), which also may be configured to communicate signaling with the interface block 220-b. Each data interface 330 may include corresponding buses and circuitry, the operation of which may be associated with (e.g., controlled by, coordinated with, operated based on) control signaling via the control interface 310. Although the example of interface block 260-b includes two such data interfaces 330 associated with the control interface 310 (e.g., in a “channel pair” arrangement), the described techniques for an interface block 260 may include any quantity of one or more data interfaces 330, and associated buses and circuitry, for a given control interface 310 of the interface block 260. Each data interface 330 may be associated with respective data path circuitry, which may include respective first-in-first-out (FIFO) and serialization/deserialization (SERDES) circuitry (e.g., FIFO/SERDES), respective write/sense circuitry 350, respective synchronization and sequencing circuitry (e.g., sync/seq logic 360), and respective timing circuitry 370, along with interconnecting signal paths (e.g., one or more buses). However, in some other examples, data path circuitry may be arranged in a different manner, or may include different circuitry components, which may include circuitry that is dedicated to respective data paths, or shared among data paths, or various combinations thereof. Each data interface 330 also may be associated with a respective set of one or more memory arrays 250. In some examples, each memory array 250 may be understood to include respective addressing circuitry such as bank logic or decoders (e.g., a row decoder, a column decoder), among other array circuitry (e.g., sense amplifiers, latches). However, in some other examples, at least a portion of such circuitry may be included in the interface block 260.

Each data interface 330 may include circuitry (e.g., one or more latches, one or more drivers) configured to communicate (e.g., receive, transmit) data signaling (e.g., modulated data signaling, DQ signaling) over a respective bus 303 (e.g., associated with a data channel). Each data interface 330 also may include circuitry to communicate clock signaling over a respective bus 304 (e.g., associated with a clock channel, such as a data clock channel), which may support clock signal reception by the data interface 330 (e.g., first clock signaling associated with the data interface 330, clock signaling having one or more phases, such as true and complement phases, DQS_t/c signaling from the interface block 220-b, clock signaling associated with data reception or write operations), or clock signal transmission by the data interface 330 (e.g., second clock signaling associated with the data interface 330, RDQS_t/c signaling to the interface block 220-b, clock signaling associated with data transmission or read operations), or both. Each data interface 330 may transmit clock signaling (e.g., received clock signaling, DQS_t/c signaling) over a respective bus 332 (e.g., for timing of other operations of the interface block 260-b).

The interface controller 320 may support various control or configuration functionality of the interface block 260-b for accessing or otherwise managing operations of the coupled memory arrays 250-b. For example, the interface controller 320 may support access command coordination or configuration, latency or timing compensation, access command buffering (e.g., in accordance with a first-in-first-out FIFO or other organizational scheme), mode registers or logic for configuration settings, or test functionality, among other functions or combinations thereof. For each data path of the interface block 260 (e.g., associated with a respective data interface 330), the interface controller 320 may be configured to transmit signaling to the respective memory arrays 250 over a bus 321 (e.g., address signaling, such as a row address or row activation signaling), to transmit signaling to the respective timing circuitry 370 over a bus 322 (e.g., timing signaling, which may be based on clock signaling received via the bus 312, configuration signaling), and to transmit signaling to the respective sync/seq logic 360 over a bus 323 (e.g., timing signaling, which may be based on clock signaling received via the bus 312, configuration signaling).

For each data path, the respective timing circuitry 370 may support timing of various operations (e.g., activations, coupling operations, signal latching, signal driving) relative to timing signaling received over a bus 322. For example, timing circuitry 370 may include a timing chain (e.g., a global column timing chain) configured to generate one or more clock signals or other initiation signals for controlling operations of the respective data path, and such signaling may include transitions (e.g., rising edge transitions, falling edge transitions, on/off transitions) that are offset from, at a different rate than, or otherwise different than transitions of signaling over the bus 322 to support a given operation or combination of operations. For example, timing circuitry 370 may be configured to transmit signaling to the respective memory arrays 250 over a bus 371 (e.g., column selection signaling, column address signaling), to transmit signaling to the respective write/sense circuitry 350 over a bus 372 (e.g., latch or driver timing signaling), and to transmit signaling to the respective sync/seq logic over a bus 373 (e.g., timing signaling).

For each data path, the respective FIFO/SERDES 340 may be configured to convert between data signaling of a first bus width (e.g., a relatively wide bus width, associated with a bus 341 (e.g., a data read/write (DRW) bus), having a relatively larger quantity of signal paths) and a second bus width (e.g., a relatively narrow bus width, associated with a bus 331, having a relatively smaller quantity of signal paths). In some examples, such a conversion may be accompanied by changing a rate of signaling between the bus 341 and the bus 331 (e.g., to maintain a given throughput). For example, a FIFO/SERDES 340 may support a conversion between the bus 341 having a bus width of 288 signal paths (e.g., for signaling Dat[287:0]) and the bus 331 having a bus width of 72 signal paths (e.g., for signaling DQ[71:0]), in which case a rate of signaling over the bus 331 may be four times as fast as a rate of signaling over the bus 341. In various examples, the FIFO/SERDES may receive data signaling over the bus 331 and transmit data signaling over the bus 341 (e.g., to support a write operation), or may receive data signaling over the bus 341 and transmit data signaling over the bus 331 (e.g., to support a read operation). In some examples (e.g., to support a read operation), the FIFO/SERDES 340 may be configured to transmit clock signaling (e.g., RDQS_t/c signaling) to the data interface 330, which may be forwarded to the interface block 220-b (e.g., over a bus 304, for reception of data signaling by the interface block 220-b received over a bus 331).

The timing or other synchronization of operations performed by the FIFO/SERDES 340 may be supported by one or more clock signals, among other signaling, received from the respective sync/seq logic 360 (e.g., over a bus 361). For example, the sync/seq logic 360 may generate or otherwise coordinate clock signaling to support the different rates of signaling of the bus 331 and the bus 341 (e.g., based on clock signaling received over a bus 332 and a bus 373). Additionally, or alternatively, the FIFO/SERDES 340 may operate in a direction (e.g., for data transmission to a data interface 330, for data reception from a data interface 330) or other mode based on configuration signaling received from the sync/seq logic 360.

For each data path, the respective write/sense circuitry 350 may be configured to support the accessing (e.g., data signaling, write signaling, read signaling) of the respective set of one or more memory arrays 250. For example, the write/sense circuitry 350 may be coupled with the memory arrays 250 over a bus 351 (e.g., a global input/output (GIO) bus), which may include respective signal paths associated with each memory array 250, or may include signal paths that are shared for all of the memory arrays 250 of the set, in which case the memory array circuitry may include multiplexing circuitry operable to couple the bus 351 with a selected one of the memory arrays 250. In some examples, a bus 351 may include a same quantity of signal paths as a bus 341 (e.g., for signaling GIO[287:0]). In some examples, a bus 351 may include a same quantity of signal paths as a quantity of columns in each memory array 250. In some other examples, the memory arrays 250 may include a quantity of columns that is an integer multiple of the quantity of signal paths of a bus 351, in which case the memory array circuitry (e.g., each memory array 250) may include decoding circuitry operable to couple a subset of columns of memory cells, or associated circuitry, with the bus 351.

To support write operations, the write/sense circuitry 350 may be configured to drive signaling (e.g., over the bus 351) that is operable to write one or more logic states to memory cells of the memory arrays 250 (e.g., based on data received over a bus 341, based on timing signaling received over a bus 371, based on data signaling received over a bus 303 and on control signaling received over a bus 301). In some examples, such signaling may be transmitted to supporting circuitry of or otherwise associated with the memory arrays 250 (e.g., as an output of signals corresponding to logic states to be written), such as sense amplifier circuitry, voltage sources, current sources, or other driver circuitry operable to apply a bias across a storage element of the memory cells (e.g., across a capacitor, across a ferroelectric capacitor), or apply a charge, a current, or other signaling to a storage element of the memory cells (e.g., to apply a current to a chalcogenide or other configurable memory material, to apply a charge to a gate of a NAND memory cell), among other examples.

To support read operations, the write/sense circuitry 350 may be configured to receive signaling (e.g., over the bus 351) that the write/sense circuitry 350 may further amplify for communication through the interface block 260-b. For example, the write/sense circuitry 350 may be configured to receive signaling corresponding to logic states read from the memory arrays 250, but at a relatively low driver strength (e.g., relatively ‘analog’ signaling, which may be associated with a relatively low drive strength of sense amplifiers of the memory arrays 250, such as p-type n-type sense amplifiers (PNSA)). The write/sense circuitry 350 may thus include further sense amplification (e.g., a data sense amplifier (DSA) or other latch between each signal path of the bus 351 and a respective signal path of the bus 341), which each may have a relatively high drive strength (e.g., for driving relatively ‘digital’ signaling over the bus 341).

The features of the architecture 300 may be duplicated in various quantities and arrangements to support a semiconductor system having multiple dies, such as various examples of a system 200. In an example implementation, each die 240 may be configured with 64 instances of the interface block 260-b (e.g., 64 units 262-b, each associated with one or more data paths), which may support a data signaling width of 9,216 signal paths for each die 240 (e.g., where each bus 303 of a channel pair is associated with 72 signal paths). For a system 200 having a stack of eight dies 240 coupled with a die 205, the die 205 may thus be configured with 512 instances of the interface block 220-b, thereby supporting an overall data signaling width of 73,738 signal paths for the system 200. However, in other implementations, dies 205 and dies 240 may be configured with different quantities of interface blocks 220 and 260, respectively, and a system 200 may be configured with different quantities of dies 240 per die 205. By dividing memory access circuitry among multiple semiconductor dies (e.g., a die 205 and one or more dies 240) in accordance with one or more of the described techniques, a system 200 may thus be configured with an increased throughput of information, or a greater storage density, among other advantages, compared with other techniques for configuring a memory system

FIG. 4 illustrates an example of a wafer layout 400 (e.g., a layout of a semiconductor wafer, a layout of a semiconductor component) that supports techniques for modular die configurations for multi-channel memory in accordance with examples as disclosed herein. The wafer layout 400 may include an array of channels coupled with one or more respective memory arrays, which may be formed on a semiconductor substrate, such as a semiconductor wafer, an SOI substrate, or epitaxial semiconductor materials formed on another substrate, among other examples. The wafer layout 400 may illustrate a portion of layout of a circular semiconductor wafer, among other wafer shapes, and aspects of the wafer layout 400 may be repeated along the x-direction, the y-direction, or both to form the semiconductor wafer. The wafer layout 400 may support manufacturing of multiple die layouts 410 (e.g., a first die layout 410-a, a second die layout 410-b), each of which may be implemented in an example of a die 240 (e.g., a memory die). For example, various subsets of the arrays and channels may be grouped into die layouts 410, and corresponding dies 240 may be formed by separating (e.g., dividing, cutting) a wafer formed in accordance with the wafer layout 400 along separation regions 415. In some cases, dies 240 formed in accordance with die layouts 410 may be stacked to form a multi-die stack.

The wafer layout includes array regions 405, each of which may include one or more memory arrays 250. In some examples, the one or more memory arrays 250 of an array region 405 may be coupled with one or more corresponding channels via circuitry of an interface block (e.g., an interface block 260), which may be associated with a respective bus 265. In some examples, each array region 405, or a subset or multiple thereof, may be associated with a respective bus 303 and a respective bus 304 (e.g., associated with data channel and a clock channel, respectively), and one or more array regions 405 may be associated with a shared bus 301 and a shared bus 302 (e.g., where a multiple array regions 405 associated with a unit 262 may be operable in accordance with a common control interface 310 and a common interface controller 320). Signal paths of each channel may include or may be coupled with one or more contacts, such as a contact 270, which may support communicating signaling with another interface block (e.g., with an interface block 220 of a die 205).

The wafer layout 400 also includes contact regions 420, each of which may extend along the x-direction. The contact regions 420 include contacts, such as at least a subset of the contacts 270 associated with the units 262 of the wafer layout 400. For example, the contact regions 420 may include contacts 270 associated with at least buses 303 and buses 304, associated with data paths of the units 262 and, in some examples, contacts 270 associated with buses 301 and buses 302, associated with control signaling. In some examples (e.g., to support stacking multiple dies 240), contact regions 420 may also include contacts 275, contacts 280, and contacts 285, as well as buses 290, where applicable. The contact regions 420 may include contacts configured for communicating signaling associated with the accessing memory arrays 250 of the array regions 405 (e.g., memory arrays 250 that are located along the y-direction from a corresponding portion of the contact regions 420). For example, the contact region 420-a-1 may include contacts coupled with and configured to communicate signaling associated with at least the array regions 405-a-1 and 405-a-2, among other array regions 405 along the x-direction. In some examples, a contact region 420 may divide a set of array regions 405 (e.g., may extend across a central portion, along the y-direction, of the array regions 405), which may allow for a similar length of a signal path from memory arrays 250 associated with the array regions 405 to an associated contact region 420. In some examples, one or more memory arrays 250 of an array region 405 may be associated with a region 425, which may include at least some signal paths for routing signaling between a contact region 420 and the memory arrays 250 of the array region 405. In some examples, regions 425 may be associated with respective data paths, and may include at least a portion of the data path circuitry (e.g., aspects of write/sense circuitry 350, timing circuitry 370, FIFO/SERDES 340, data interfaces 330, or any combination thereof, among other circuitry). Additionally, or alternatively, at least a portion of the data path circuitry may be included in contact regions 420.

The wafer layout 400 also includes control regions 430, which may extend along the y-direction. The control regions 430 may include control circuitry for operating memory arrays 250 of the array regions 405 (e.g., memory arrays 250 that are located along the x-direction from a corresponding portion of the control regions 430). For example, a control region 430-a-1 may include control circuitry configured to operate memory arrays 250 of array regions 405 on one or both sides of the control region 430-a-1 (e.g., array regions 405-a-1 and 405-a-2, which may be associated with at least a channel pair configuration). In some examples, control regions 430 may include or may implement aspects of an interface block 260. For example, control regions 430 may include circuitry associated with control interfaces 310 and interface controllers 320. In some examples, control regions 430 may also include contacts associated with such control circuitry, such as contacts 270 associated with a bus 301 and a bus 302. In some examples, control regions 430 may also include at least a portion of circuitry associated with data paths, such as circuitry associated with timing circuitry 370, sync/seq logic 360, write/sense circuitry 350, FIFO/SERDES 340, or a combination thereof. In some examples, the control regions 430 may include one or more fuse arrays, one or more pumps, one or more regulators, one or more voltage sources, or a combination thereof.

The wafer layout 400 may be organized into a set of independently-operable units 435 (e.g., modules), each of which may correspond to a unit 262. Each unit 435 may include memory arrays 250 of a set of one or more array regions 405 and circuitry (e.g., control circuitry, signal paths) to operate the memory arrays 250 without reliance on or involvement of a separate unit 435. For example, a unit 435-a may include memory arrays 250 of included array regions 405 and a portion of the control region 430-a-1 included in the unit 435-a, which may include at least a portion of the control circuitry for operating the included memory arrays 250. Each unit 435 may also include contacts configured for communicating signaling associated with accessing the included memory arrays 250. For example, as illustrated, the unit 435-a may include a portion of the contact region 420-a-2, which may include contacts 270 associated with communicating at least data signaling (e.g., of a bus 303) associated with the memory arrays 250 of the unit 435-a (e.g., along the positive and negative y-direction from the contact region 420-a-2). Each of the array regions 405 of the unit 435-a, among other units 435, may include one or more rows of memory arrays 250 (e.g., positioned along the y-direction), and one or more columns of memory arrays 250 (e.g., positioned along the x-direction).

The wafer layout 400 also includes separation regions 415 (e.g., extending along the x-direction, extending along the y-direction), which may be examples of scribe lines or other physical delineations (e.g., isolations) between units 435. For example, the wafer layout 400 may include a first set of separation regions 415-a extending along the y-direction (e.g., parallel with the control regions 430) and a second set of separation regions 415-b extending along the x-direction (e.g., parallel with the contact regions 420-a). In some cases, consecutive separation regions 415-a (e.g., adjacent separation regions 415-a along the x-direction) and consecutive separation regions 415-b (e.g., adjacent separation regions 415-b along the y-direction) may located at boundaries between units 435. For example, a portion of a control region 430 associated with the unit 435-a may be between a separation region 415-b-1 and a separation region 415-b-2, and a portion of a contact region 420 associated with the unit 435-a may be between a separation region 415-a-1 and a separation region 415-a-2.

In some examples, separation regions 415, contact regions 420, and control regions 430 may be arranged according to a pitch (e.g., a dimension of repetition, a unit pitch) along one or more directions. For example, the separation regions 415-a, the control regions 430, or both may be arranged along the x-direction according to a first pitch. That is, the distance between consecutive separation regions 415-a along the x-direction may be the same or substantially the same as the distance between consecutive control regions 430 along the x-direction. Additionally, or alternatively, the separation regions 415-b, the contact regions 420, or both may be arranged along the y-direction according to a second pitch. That is, the distance between consecutive separation regions 415-b along the y-direction may be the same or substantially the same as the distance between consecutive contact regions 420 along the y-direction. Although FIG. 4 depicts the first pitch as being greater than the second pitch, other combinations of pitches may be implemented for different configurations (e.g., for different dimensions or aspect ratios of units 435). For example, the first and second pitches may be equal, or the second pitch may be greater than the first pitch, among other examples.

One or more configurations of die layouts 410 may be identified from the wafer layout 400. Such a configuration may indicate a subset of the separation regions 415 for subdividing a wafer, such that separating the wafer along the indicated separation regions 415 forms dies (e.g., dies 240) corresponding to the one or more die layouts 410 of the configuration. Additionally, or alternatively, the configuration of one or more die layouts 410 may indicate a subset of control regions 430, such that separating the wafer layout 400 along the indicated control regions 430 forms the one or more die layouts 410 of the configuration. That is, a subset of control regions 430 may be cut (e.g., diced) as part of forming one or more dies in accordance with the one or more die layouts 410. In some such cases, control circuitry of the indicated control regions 430 used for such cutting may be deactivated (e.g., inoperable, deactivated by a configuration).

A configuration of die layouts 410 may indicate a same aspect ratio for each of the one or more die layouts 410, or the configuration may indicate different aspect ratios for the one or more die layouts 410. Additionally, or alternatively, a configuration may indicate a same set of dimensions or a different set of dimensions for each of the one or more die layouts 410, where a dimension may refer to a length along a direction or some multiple or other measurement according to units 435. For example, the configuration may indicate a first dimension of a first die layout 410 along the x-direction and a second dimension of the first die layout 410 along the y-direction. The configuration may further indicate a third dimension of a second die layout 410 along the x-direction and a fourth dimension of the second die layout 410 along the y-direction. Each dimension of the first and second die layouts 410 may be the same or different.

In some examples, an array region 405, or one or more memory arrays 250 thereof, may be associated with (e.g., may be configured to be operated by) multiple control regions 430. For example, the array region 405-a-2 may be associated with a first control region 430-a-1 and may be associated with a second control region 430-a-2. Accordingly, the array region 405-a-2 may be operated by either the control region 430-a-1 or the control region 430-a-2, depending on the configuration of the one or more die layouts 410. In some examples, a unit 435 may be subdivided, such as being cut along the y-direction to omit at least a portion of an array region 405 and a corresponding portion of a contact region 420, which may be implemented in a subdivided unit 435 having fewer channels (e.g., fewer buses 303, a lower information bandwidth) than a full unit 435.

In some examples (e.g., as part of identifying the configuration of one or more dies), an error detection operation may be performed on a wafer formed in accordance with the wafer layout 400 (e.g., during manufacturing of the wafer, during an operation to determine how to subdivide the wafer). For example, each of the channels and associated array regions 405 may undergo functional testing (e.g., using the contact regions 420 and the control regions 430) to evaluate the wafer for defects associated with the tested array regions 405, such as manufacturing defects or other defects which may limit integrity of data stored at the associated memory arrays 250 or other operability. Such functional testing may include generating an error map indicating whether a defect was detected in one or more one or more memory arrays 250 or associated channels. Such an error map may be evaluated as part of identifying a configuration for subdividing a wafer formed in accordance with the wafer layout 400, such that array regions 405 or memory arrays 250 thereof, and associated channels, in which a defect was detected may not be included in one or more die layouts 410 indicated by a wafer subdivision configuration. In some cases, an indication of detected defects may be stored at the wafer itself (e.g., at a storage location of the wafer, such as one or more memory cells, or one or more fuses or antifuses, among other storage locations). For example, an indication of a detected defect of a particular array region 405 or associated channels may be stored in a control region 430 associated with the particular array region 405 (e.g., stored in a fuse array of the corresponding portion of the control region 430).

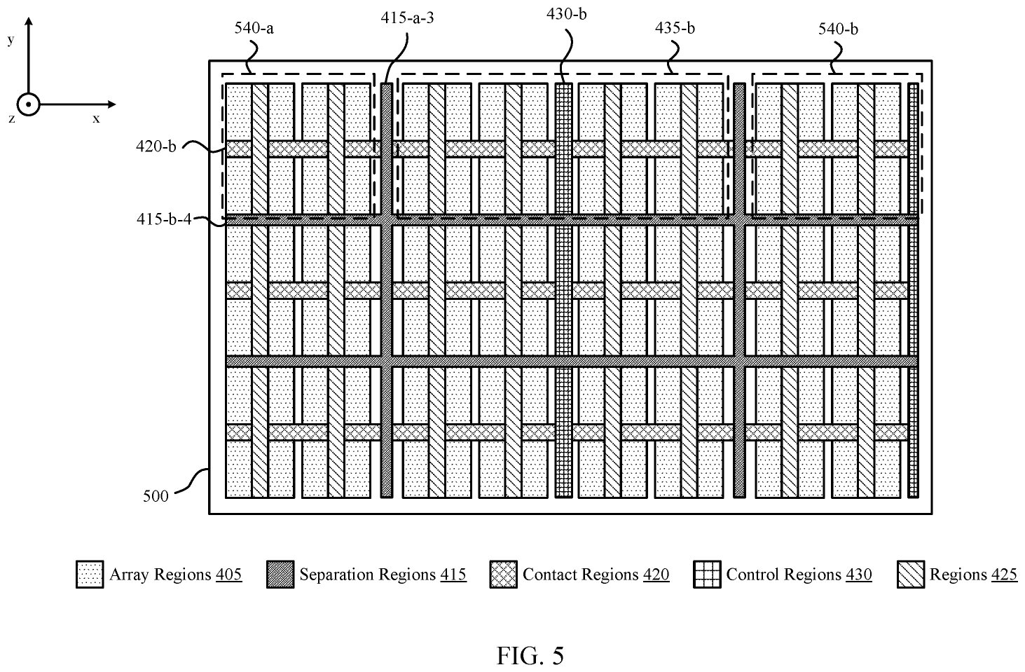

FIG. 5 illustrates an example of a die 500 (e.g., a semiconductor die, a memory die, a semiconductor subcomponent, a die 240) that supports techniques for modular die configurations for multi-channel memory in accordance with examples as disclosed herein. The die 500 may be an example of subdividing a wafer, formed in accordance with the wafer layout 400, based on an identified die layout 410 (e.g., after a separation along separation regions 415 and, in some cases, control regions 430). The die 500 may include one or more units 435 (e.g., unit 435-b). Additionally, the die 500 may include one or more unit portions 540, such as a unit portions 540-a and 540-b, each of which may be a portion of a respective unit 435. In some cases, such as with reference to the unit portion 540-b, a unit portion 540 may be formed if a wafer is separated along a control region 430. For example, separation along a control region 430 may subdivide a unit 435 into a first unit portion 540 and a second unit portion 540. In such examples, the first unit portion 540 (e.g., the unit portion 540-b) may be included in a first die (e.g., the die 500), and the second unit portion 540 may be included in a second die, such as a second die formed in accordance with the wafer layout 400.

The die 500 may include an array of channels and associated memory arrays 250 of one or more array regions 405. In some cases, the die 500 may include one or more separation regions 415, which may be separation regions that were not used for subdividing a wafer and, therefore, may remain in the die 500. That is, the separation regions 415 in the die 500 may be separation regions 415-a of a wafer layout 400 which were not cut (e.g., not diced) as part of forming the die 500 (e.g., leftover or replicant scribe lines). Accordingly, such separation regions 415 of the die 500 may not be used to support operation of the die 500. The die 500 may also include at least one contact region 420 (e.g., contact region 420-b), and at least one control region 430 (e.g., control region 430-b), each of which may be a respective portion of such regions of a wafer formed in accordance with the wafer layout 400.

The die 500 may have an associated aspect ratio related to a quantity of channels and associated one or more memory arrays 250 along the x-direction and the y-direction (e.g., the quantity of rows and columns of channels, a quantity of rows and columns of units 435, or portions thereof). For example, the die 500 may have an aspect ratio of eight by three (8×3) channels, which may correspond to eight regions 425 arranged along the x-direction and three contact regions 430 arranged along the y-direction. The aspect ratio of a die 500 may be a functional attribute of the dies 500, and may correspond to properties of memory storage and architecture of the die 500. For example, because each channel (e.g., each bus 303) may be associated with a respective one or more memory arrays 250, the total storage capacity and bandwidth (e.g., data transfer bandwidth, data transfer rate) of a die 500 may be proportional to the quantity of channels of the die 500.

In some examples, an aspect ratio of the die 500 may affect stacking capabilities of the die 500. For example, an architecture of a memory system that includes one or more dies 500 may depend on the aspect ratios of the one or more dies 500. A plurality of dies 500 may be placed in a stack (e.g., along the z-direction) to form a multi-die stack memory system. To support such an architecture, the aspect ratios of each of the one or more memory dies 500 may be the same or similar, which may allow for bonding areas (e.g., hybrid bonding locations), signal contact locations (e.g., locations of contacts 270, contacts 275, contacts 280, contacts 285, or a combination thereof), and power supply contact locations to align across different memory dies 500. In some implementations, the one or more dies 500 may be arranged on a planar logic layer (e.g., a die 205), or multiple vertical stacks of dies 500 may be arranged on a planar logic layer. To support such architectures, aspects ratios of the one or more memory dies 500 may be selected such that bonding areas, signal contact locations, and supply contact locations of the one or more dies 500 align with corresponding locations of the planar logic layer.

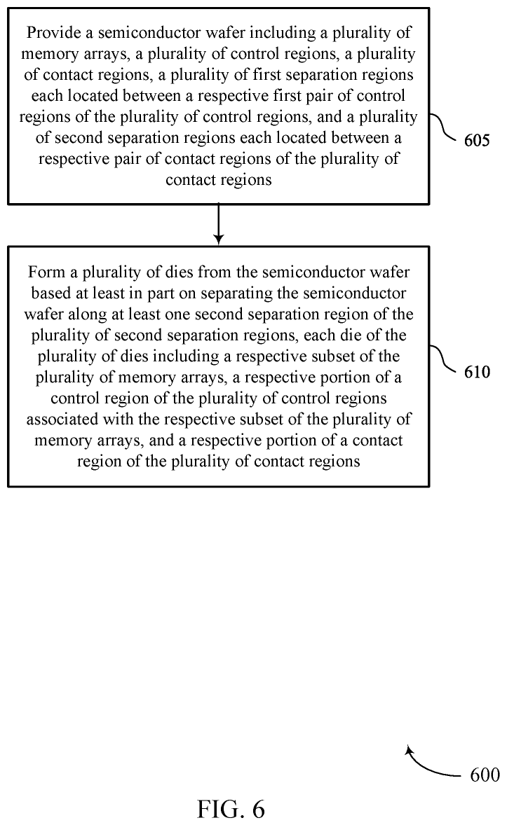

FIG. 6 illustrates a flowchart illustrating a method or methods 600 that techniques for modular die configurations for multi-channel memory in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method 600 may include providing a semiconductor wafer including a plurality of memory arrays, a plurality of control regions, a plurality of contact regions, a plurality of first separation regions each located between a respective first pair of control regions of the plurality of control regions, and a plurality of second separation regions each located between a respective pair of contact regions of the plurality of contact regions. In some examples, each control region of the plurality of control regions may extend along a first direction and may include control circuitry associated with accessing memory arrays of the plurality of memory arrays that are located along a second direction from the control region, and each first separation region of the plurality of first separation regions may extend along the first direction. In some examples, each contact region of the plurality of contact regions may extend along the second direction and may include contacts configured for communicating signaling associated with the accessing memory arrays of the plurality of memory arrays that are located along the first direction from the contact region, and each second separation region of the plurality of separation regions may extend along the second direction.

At 610, the method 600 may include forming a plurality of dies from the semiconductor wafer based at least in part on separating the semiconductor wafer along at least one second separation region of the plurality of second separation regions, each die of the plurality of dies including a respective subset of the plurality of memory arrays, a respective portion of a control region of the plurality of control regions associated with the respective subset of the plurality of memory arrays, and a respective portion of a contact region of the plurality of contact regions.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for providing a semiconductor wafer including a plurality of memory arrays, a plurality of control regions, a plurality of contact regions, a plurality of first separation regions each located between a respective first pair of control regions of the plurality of control regions, and a plurality of second separation regions each located between a respective pair of contact regions of the plurality of contact regions. In some examples, each control region of the plurality of control regions may extend along a first direction and may include control circuitry associated with accessing memory arrays of the plurality of memory arrays that are located along a second direction from the control region, and each first separation region of the plurality of first separation regions may extend along the first direction. In some examples, each contact region of the plurality of contact regions may extend along the second direction and may include contacts configured for communicating signaling associated with accessing memory arrays of the plurality of memory arrays that are located along the first direction from the contact region, and each second separation region of the plurality of separation regions may extend along the second direction. In some examples, the method, apparatus, or non-transitory computer-readable medium may include operations, features, circuitry, logic, means, or instructions, or any combination thereof for forming a plurality of dies from the semiconductor wafer based at least in part on separating the semiconductor wafer along at least one second separation region of the plurality of second separation regions, each die of the plurality of dies including a respective subset of the plurality of memory arrays, a respective portion of a control region of the plurality of control regions associated with the respective subset of the plurality of memory arrays, and a respective portion of a contact region of the plurality of contact regions.

Aspect 2: The method, apparatus, or non-transitory computer-readable medium of aspect 1, where the semiconductor wafer is configured in accordance with a plurality of units, each unit of the plurality of units including: a respective subset of one or more memory arrays of the plurality of memory arrays; a respective portion of a contact region of the plurality of contact regions, the memory arrays of the respective subset located along the first direction from the respective portion of the contact region, and the contacts of the respective portion of the contact region associated with signaling of a respective plurality of channels; and a respective portion of a control region of the plurality of control regions, the memory arrays of the respective subset located along the second direction from the respective portion of the contact region, and the control circuitry of the respective portion of the contact region associated with the signaling of the respective plurality of channels.

Aspect 3: The method, apparatus, or non-transitory computer-readable medium of aspect 2, where, for at least one unit of the plurality of units, the respective portion of the control region includes one or more fuse arrays, one or more pumps, one or more regulators, one or more voltage sources, or a combination thereof for operating the respective subset of one or more memory arrays.

Aspect 4: The method, apparatus, or non-transitory computer-readable medium of any of aspects 2 through 3, further including operations, features, circuitry, logic, means, or instructions, or any combination thereof for forming the plurality of dies based at least in part on identifying one or more defects associated with a unit of the plurality of units.

Aspect 5: The method, apparatus, or non-transitory computer-readable medium of aspect 4, where identifying the one or more defects includes operations, features, circuitry, logic, means, or instructions, or any combination thereof for reading a stored indication of the one or more defects from a storage location of the semiconductor wafer.

Aspect 6: The method, apparatus, or non-transitory computer-readable medium of any of aspects 2 through 5, where the plurality of dies includes a first die having a first portion of a unit of the plurality of units, and a second die having a second portion of the unit.

Aspect 7: The method, apparatus, or non-transitory computer-readable medium of any of aspects 1 through 6, where the plurality of control regions are arranged according to a first pitch and the plurality of first separation regions are arranged according to the first pitch; and the plurality of contact regions are arranged according to a second pitch and the plurality of second separation regions are arranged according to the second pitch.

Aspect 8: The method, apparatus, or non-transitory computer-readable medium of any of aspects 1 through 7, where a die of the plurality of dies includes a plurality of portions of respective control regions of the plurality of control regions.

Aspect 9: The method, apparatus, or non-transitory computer-readable medium of any of aspects 1 through 8, further including operations, features, circuitry, logic, means, or instructions, or any combination thereof for forming the plurality of dies based at least in part on cutting the semiconductor wafer along a control region of the plurality of control regions.

Aspect 10: The method, apparatus, or non-transitory computer-readable medium of any of aspects 1 through 9, where the plurality of first separation regions includes respective scribe lines of the semiconductor wafer.

Aspect 11: The method, apparatus, or non-transitory computer-readable medium of any of aspects 1 through 10, where the plurality of dies includes a first die having a first dimension along the first direction and a second dimension along the second direction, and a second die having a third dimension along the first direction and a fourth dimension along the second direction and the third dimension is different than the first dimension, or the fourth dimension is different than the second dimension, or both.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: An apparatus, including: a semiconductor wafer including: a plurality of memory arrays; a plurality of control regions, each control region of the plurality of control regions extending along a first direction and including control circuitry associated with accessing memory arrays of the plurality of memory arrays that are located along a second direction from the control region; a plurality of contact regions, each contact region of the plurality of contact regions extending along the second direction and including contacts configured for communicating signaling associated with accessing memory arrays of the plurality of memory arrays that are located along the first direction from the contact region; a plurality of first separation regions extending along the first direction, each first separation region of the plurality of first separation regions located between a respective first pair of control regions of the plurality of control regions; and a plurality of second separation regions extending along the second direction, each second separation region of the plurality of second separation regions located between a respective pair of contact regions of the plurality of contact regions.

Aspect 13: The apparatus of aspect 12, where the semiconductor wafer is configured in accordance with a plurality of units, each unit of the plurality of units including: a respective subset of one or more memory arrays of the plurality of memory arrays; a respective portion of a contact region of the plurality of contact regions, the memory arrays of the respective subset located along the first direction from the respective portion of the contact region, and the contacts of the respective portion of the contact region associated with signaling of a respective plurality of channels; and a respective portion of a control region of the plurality of control regions, the memory arrays of the respective subset located along the second direction from the respective portion of the contact region, and the control circuitry of the respective portion of the contact region associated with the signaling of the respective plurality of channels.

Aspect 14: The apparatus of aspect 13, where, for at least one unit of the plurality of units, the respective portion of the control region includes one or more fuse arrays, one or more pumps, one or more regulators, one or more voltage sources, or a combination thereof for operating the respective subset of one or more memory arrays.

Aspect 15: The apparatus of any of aspects 12 through 14, where: the plurality of control regions are arranged along the second direction according to a first pitch and the plurality of first separation regions are arranged along the second direction according to the first pitch; and the plurality of contact regions are arranged along the first direction according to a second pitch and the plurality of second separation regions are arranged along the first direction according to the second pitch.

Aspect 16: The apparatus of any of aspects 12 through 15, where each first separation region of the plurality of first separation regions includes a respective scribe line of the semiconductor wafer.

An apparatus is described. The following provides an overview of aspects of the apparatus as described herein:

Aspect 17: An apparatus, including: a plurality of memory arrays of a memory die; a plurality of channels of the memory die associated with accessing the plurality of memory arrays; one or more control regions of the memory die, each control region of the one or more control regions extending along a first direction and including control circuitry associated with accessing memory arrays of the plurality of memory arrays that are located along a second direction from the control region; one or more contact regions of the memory die, each contact region of the one or more contact regions extending along the second direction and including contacts configured for communicating signaling associated with accessing memory arrays of the plurality of memory arrays that are located along the first direction from the contact region; and one or more separation regions of the memory die extending along the first direction, each separation region of the one or more separation regions disposed between a control region of the one or more control regions and a respective border of the apparatus.

Aspect 18: The apparatus of aspect 17, further including: one or more second separation regions of the memory die extending along the second direction, each second separation region of the one or more second separation regions disposed between a respective pair of contact regions of the one or more contact regions.

Aspect 19: The apparatus of any of aspects 17 through 18, where the apparatus is configured in accordance with one or more units, each unit of the one or more units including: a respective subset of one or more memory arrays of the plurality of memory arrays and a respective subset of one or more channels of the plurality of channels; a respective portion of a contact region of the one or more contact regions, the memory arrays of the respective subset located along the first direction from the respective portion of the contact region, and the contacts of the respective portion of the contact region associated with signaling of the respective subset of one or more channels; and a respective portion of a control region of the one or more control regions, the memory arrays of the respective subset of one or more memory arrays located along the second direction from the respective portion of the contact region, and the control circuitry of the respective portion of the contact region associated with the signaling of the respective subset of one or more channels.

Aspect 20: The apparatus of any of aspects 17 through 19, where each separation region of the one or more separation regions includes a respective scribe line of the apparatus.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a semiconductor wafer comprising:
a plurality of memory arrays;
a plurality of control regions, each control region of the plurality of control regions extending along a first direction and comprising control circuitry associated with accessing memory arrays of the plurality of memory arrays that are located along a second direction from the control region;
a plurality of contact regions, each contact region of the plurality of contact regions extending along the second direction and comprising contacts configured for communicating signaling associated with accessing memory arrays of the plurality of memory arrays that are located along the first direction from the contact region;
a plurality of first separation regions extending along the first direction, each first separation region of the plurality of first separation regions located between a respective first pair of control regions of the plurality of control regions; and
a plurality of second separation regions extending along the second direction, each second separation region of the plurality of second separation regions located between a respective pair of contact regions of the plurality of contact regions.

2. The apparatus of claim 1, wherein the semiconductor wafer is configured in accordance with a plurality of units, each unit of the plurality of units comprising:
a respective subset of one or more memory arrays of the plurality of memory arrays;
a respective portion of a contact region of the plurality of contact regions, the memory arrays of the respective subset located along the first direction from the respective portion of the contact region, and the contacts of the respective portion of the contact region associated with signaling of a respective plurality of channels; and
a respective portion of a control region of the plurality of control regions, the memory arrays of the respective subset located along the second direction from the respective portion of the contact region, and the control circuitry of the respective portion of the contact region associated with the signaling of the respective plurality of channels.

3. The apparatus of claim 2, wherein for at least one unit of the plurality of units, the respective portion of the control region comprises one or more fuse arrays, one or more pumps, one or more regulators, one or more voltage sources, or a combination thereof for operating the respective subset of one or more memory arrays.

4. The apparatus of claim 1, wherein:
the plurality of control regions are arranged along the second direction according to a first pitch and the plurality of first separation regions are arranged along the second direction according to the first pitch; and
the plurality of contact regions are arranged along the first direction according to a second pitch and the plurality of second separation regions are arranged along the first direction according to the second pitch.

5. The apparatus of claim 1, wherein each first separation region of the plurality of first separation regions comprises a respective scribe line of the semiconductor wafer.

6. An apparatus, comprising:
a plurality of memory arrays of a memory die;
a plurality of channels of the memory die associated with accessing the plurality of memory arrays;
one or more control regions of the memory die, each control region of the one or more control regions extending along a first direction and comprising control circuitry associated with accessing memory arrays of the plurality of memory arrays that are located along a second direction from the control region;
one or more contact regions of the memory die, each contact region of the one or more contact regions extending along the second direction and comprising contacts configured for communicating signaling associated with accessing memory arrays of the plurality of memory arrays that are located along the first direction from the contact region; and
one or more separation regions of the memory die extending along the first direction, each separation region of the one or more separation regions disposed between a control region of the one or more control regions and a respective border of the apparatus.

7. The apparatus of claim 6, further comprising:
one or more second separation regions of the memory die extending along the second direction, each second separation region of the one or more second separation regions disposed between a respective pair of contact regions of the one or more contact regions.

8. The apparatus of claim 6, wherein the apparatus is configured in accordance with one or more units, each unit of the one or more units comprising:
a respective subset of one or more memory arrays of the plurality of memory arrays and a respective subset of one or more channels of the plurality of channels;
a respective portion of a contact region of the one or more contact regions, the memory arrays of the respective subset located along the first direction from the respective portion of the contact region, and the contacts of the respective portion of the contact region associated with signaling of the respective subset of one or more channels; and
a respective portion of a control region of the one or more control regions, the memory arrays of the respective subset of one or more memory arrays located along the second direction from the respective portion of the contact region, and the control circuitry of the respective portion of the contact region associated with the signaling of the respective subset of one or more channels.

9. The apparatus of claim 6, wherein each separation region of the one or more separation regions comprises a respective scribe line of the apparatus.

10. A method, comprising:
providing a semiconductor wafer comprising:
a plurality of memory arrays;
a plurality of control regions, each control region of the plurality of control regions extending along a first direction and comprising control circuitry associated with accessing memory arrays of the plurality of memory arrays that are located along a second direction from the control region;
a plurality of contact regions, each contact region of the plurality of contact regions extending along the second direction and comprising contacts configured for communicating signaling associated with accessing memory arrays of the plurality of memory arrays that are located along the first direction from the contact region;
a plurality of first separation regions extending along the first direction, each first separation region of the plurality of first separation regions located between a respective first pair of control regions of the plurality of control regions; and
a plurality of second separation regions extending along the second direction, each second separation region of the plurality of second separation regions located between a respective pair of contact regions of the plurality of contact regions; and
forming a plurality of dies from the semiconductor wafer based at least in part on separating the semiconductor wafer along at least one second separation region of the plurality of second separation regions, each die of the plurality of dies comprising a respective subset of the plurality of memory arrays, a respective portion of a control region of the plurality of control regions associated with the respective subset of the plurality of memory arrays, and a respective portion of a contact region of the plurality of contact regions.

11. The method of claim 10, wherein the semiconductor wafer is configured in accordance with a plurality of units, each unit of the plurality of units comprising:
a respective subset of one or more memory arrays of the plurality of memory arrays;
a respective portion of a contact region of the plurality of contact regions, the memory arrays of the respective subset located along the first direction from the respective portion of the contact region, and the contacts of the respective portion of the contact region associated with signaling of a respective plurality of channels; and
a respective portion of a control region of the plurality of control regions, the memory arrays of the respective subset located along the second direction from the respective portion of the contact region, and the control circuitry of the respective portion of the contact region associated with the signaling of the respective plurality of channels.

12. The method of claim 11, wherein for at least one unit of the plurality of units, the respective portion of the control region comprises one or more fuse arrays, one or more pumps, one or more regulators, one or more voltage sources, or a combination thereof for operating the respective subset of one or more memory arrays.

13. The method of claim 11, further comprising:
forming the plurality of dies based at least in part on identifying one or more defects associated with a unit of the plurality of units.

14. The method of claim 13, wherein identifying the one or more defects comprises:
reading a stored indication of the one or more defects from a storage location of the semiconductor wafer.

15. The method of claim 11, wherein the plurality of dies comprises a first die having a first portion of a unit of the plurality of units, and a second die having a second portion of the unit.

16. The method of claim 10, wherein:
the plurality of control regions are arranged according to a first pitch and the plurality of first separation regions are arranged according to the first pitch; and
the plurality of contact regions are arranged according to a second pitch and the plurality of second separation regions are arranged according to the second pitch.

17. The method of claim 10, wherein a die of the plurality of dies comprises a plurality of portions of respective control regions of the plurality of control regions.

18. The method of claim 10, further comprising:
forming the plurality of dies based at least in part on cutting the semiconductor wafer along a control region of the plurality of control regions.

19. The method of claim 10, wherein the plurality of first separation regions comprises respective scribe lines of the semiconductor wafer.

20. The method of claim 10, wherein the plurality of dies comprises:
a first die having a first dimension along the first direction and a second dimension along the second direction; and
a second die having a third dimension along the first direction and a fourth dimension along the second direction, wherein the third dimension is different than the first dimension, or the fourth dimension is different than the second dimension, or both.
